(19) United States
(12) Patent Application Publication
(10) Pub. No.: US 2015/0247888 A1
(43) Pub. Date: Sep. 3, 2015

(54) SPARK TESTING APPARATUS

(71) Applicants: Rajiv Chandra Shekhar, Pinjarra Hills (AU); Edward Gus Prochon, Pinjarra Hills (AU); Barend Jacobus Pienaar, Pinjarra Hills (AU); Paul John Lever, Pinjarra Hills (AU)

(72) Inventors: Rajiv Chandra Shekhar, Pinjarra Hills (AU); Edward Gus Prochon, Pinjarra Hills (AU); Barend Jacobus Pienaar, Pinjarra Hills (AU); Paul John Lever, Pinjarra Hills (AU)

(73) Assignee: CMTE Development Limited, Pinjarra Hills, Queensland (AU)

(21) Appl. No.: 14/415,654

(22) PCT Filed: Jul. 19, 2012
(86) PCT No.: PCT/AU2012/000864

§ 371 Date: May 18, 2015

(30) Foreign Application Priority Data
Jul. 20, 2011 (AU) 2011902910

(51) Int. Cl. G01R 31/00; G01R 19/145

(52) U.S. Cl. CPC G01R 31/001; G01R 19/145

(57) ABSTRACT

The invention provides a method and apparatus for electronically testing the safety of sources of energy such as electrical circuits, in explosive atmospheres such as high risk mining situations, using an electronic spark tester (EST) in place of the known mechanical spark test apparatus (STA). The EST typically uses an analogue subsystem (5) and a digital subsystem (6) connected by a digital to analogue converter (7) and an analogue to digital connector (8) to apply a simulated spark load to the energy source and measure the time varying current response to that load.

### FIELD OF THE INVENTION

This invention relates to spark testing apparatus and has been devised particularly though not solely for assessing the safety of energy sources used in high risk mining situations.

There are many situations where explosive atmospheres exist and present a safety hazard if those atmospheres come in contact with a source of energy such as en explosive such as from an electrical circuit. The concept of “intrinsic safety” is well recognised as a method of equipment protection in such explosive atmospheres. Protection is achieved by designing the energy source such that it is incapable of producing an explosive spark. This is achieved by limitation of the electrical energy made available by the source, either always, or when the onset of a fault is detected.

In the past, energy sources with simple electrical characteristics have been certified intrinsically safe purely on the basis of those characteristics, through the use of assessment curves. Many devices however have more complicated characteristics which are assessed using a mechanical device known as a spark test apparatus (STA). The STA is a device connected as a load to the energy source which simulates a spark in an explosive atmosphere. This is accomplished through the use of a representative flammable gas mixture which surrounds a tungsten wire held against a rapidly rotating cadmium disc configured to randomly emit a spark causing an explosion of the flammable gas mixture. The observation, or absence of an actual explosion, is the basis for assessment using a STA.

There are however, several problems affecting the usability and reliability of currently used spark test apparatus (STA) including the issue of repeatability. Although the STA simulates the spark and explosion conditions well, it does so in a random manner. Usually the STA is run for a set number of revolutions, based on the assumption that a worst case spark will occur within this set number of revolutions, This means that there is no guarantee that during a given test the energy source under test has been subjected to the worst possible fault condition.

There is also a no quantifiable result from an STA test, which is based solely on observation. If an explosion occurs during the test period, the energy source is deemed to have faded but there is no quantitative indication of safety.

A further issue with current STA apparatus is that the apparatus uses hazardous materials. Both the cadmium disc used to generate the spark and also the flammable gases surrounding the apparatus are hazardous substances with consequential health and safety issues.

The present invention therefore proposes to replace the current STA apparatus with an electronic spark testing method which performs the functions of the STA while mitigating the above mentioned issues. This alternative test according to the invention is a departure from the STA in two primary ways, namely the simulation of the fault condition and the safety assessment of the device under test.

### SUMMARY OF THE INVENTION

Accordingly, in one aspect, the present invention provides a method of assessing the safety of an energy source including the steps of applying a simulated spark load to the energy source and measuring the time varying current response to that load.

Preferably, the time varying current response measurement is used to determine the energy delivered to the load over the duration of the simulated spark.

Preferably the time varying current response measurement is also used to determine the instantaneous power.

Preferably, the measured energy and instantaneous power are used to assess whether an explosion would have occurred.

In one form of the invention the energy source is connected to an electronic spark tester, and the method includes the following steps:
performing a static test by the electronic spark tester to determine the output current to output voltage relationship of the energy source;
performing a dynamic test by the electronic spark tester to determine how the energy source responds to fast changes in load conditions; and
using the static and dynamic test results together with predetermined values for the spark load to calculate the stimulus required to yield the most energetic simulated spark.

Preferably the stimulus required to yield the most energetic simulated spark is applied to an analogue subsystem within the electronic spark tester and the resulting current/voltage response of the energy source is measured and recorded

Preferably the measured current/voltage is used to calculate the time varying power, which in turn is used to calculate a quantitative measure of ignition safely.

In a further aspect, the present invention provides apparatus for assessing the safety of an energy source including means for electronically generating a simulated spark load adapted to be applied to the energy source, and electronic means for measuring the time varying current response to that load.

Preferably, the apparatus includes a digital subsystem adapted to output control signals and an analogue system configured to replicate the dynamic characteristics of a mechanical spark testing apparatus and measure the response of the energy source.

### BRIEF DESCRIPTION OF THE DRAWINGS

Notwithstanding any other forms that may fall within its scope, one preferred form of the invention will now be described with reference to the accompanying drawings in which:

FIG. 1 is a graph showing the electrical characteristics of a typical break spark;

FIG. 2 is a concept diagram of the electronic apparatus according to the invention arranged to replicate the dynamic characteristics of a mechanical spark testing apparatus and measure their response of an energy source.

FIG. 3 is block circuit diagram showing the operation of the analogue subsystem shown in FIG. 2; and

FIG. 4 is an in-principle circuit diagram of a semiconductor circuit under the control of the digit subsystem shown in FIG. 2.

### PREFERRED EMBODIMENTS OF THE INVENTION

h the preferred form of the invention, the mechanical STA apparatus of the prior art is replaced by an electronic circuit which both generates and measures the impact or the characteristics of a spark of the type previously generated by a mechanical spark testing apparatus (STA).

The STA creates sparks randomly, with no certainty as to when an explosion will be created (if at all). As the STA is connected as a load to the energy source under test, the sparks it generates can be analysed purely in terms of their electrical characteristics.

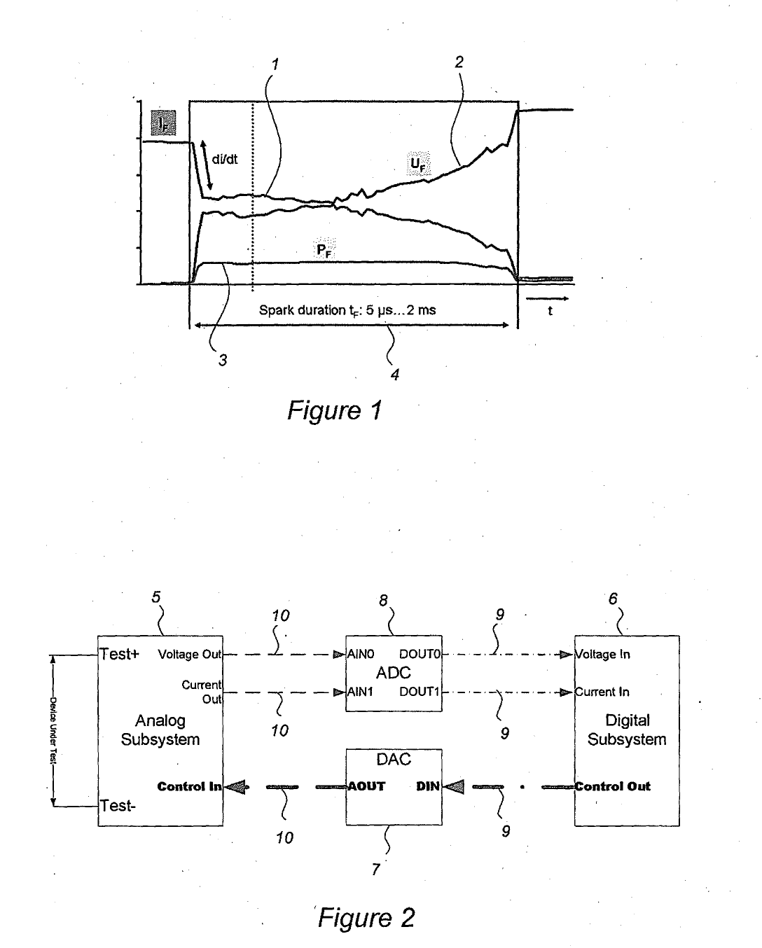

Specifically, a spark can be considered to be a time varying electrical load. This means that the voltage across and current flowing through the spark over its duration, fully describe it. The electrical characteristics of a typical break spark are shown in FIG. 1 where the current 1 and voltage 2 characteristics together with the instantaneous power 3 are shown over the duration of the spark represented by time span 4.

The definition and description of a spark in this manner creates the possibility of simulating an explosive spark by an electronic device configured to attempt to force the voltage profile shown in FIG. 1 at the terminals of the energy source under test. This removes the need to actually create a spark and/or explosion. The realisation of this concept according to the invention is achieved by providing a time varying electronically controllable load.

Once the real spark and explosion of a STA is replaced with a simulated spark load of the type described above with reference to FIG. 1, a method for assessing the safety of the energy source under test then needs to be formulated. This method, according to the invention, involves measurement of the time varying current response to a simulated spark load. This measurement can then be used to determine the energy delivered to the load under the simulated spark's duration, as well as the instantaneous power. Using the energy and instantaneous power, an assessment is made as to whether an explosion would have occurred.

This is achieved by providing a semiconductor device configured to function as a controllable electronic load, and PC based data acquisition and waveform generation system providing the control and measurement functions. This embodiment of the invention, termed an electronic spark tester (EST) is described further below.

The EST, when connected as a load to an energy supply, simulates the electrical characteristics of an STA including time varying energy dissipation (resistance), and time varying energy storage (capacitance/inductance).

In an STA these characteristics are the result of repeated making and breaking of physical contact between a tungsten wire and a cadmium disc and arcing in between the making and breaking of this physical contact.

The EST analyses the energy sources response to these simulated load characteristics and based on this analysis produces a result enabling a quantitative assessment of the energy sources propensity to cause an explosive spark.

At a conceptual level, this is achieved by a device consisting of two subsystems as shown in FIG. 2.

The subsystems comprise an analogue subsystem 5 and a digital subsystem 6 connected by a digital to analogue converter 7 and an analogue to digital converter 5 as shown in FIG. 2, The digital signals are represented by lines 9 and the analogue signals by lines 10 with the arrows in FIG. 2 indicating the direction of signal flow. Bold names and arrows indicate vector valued signals.

The analogue subsystem 5 outputs two measurement signals, namely voltage and current measurements. These are converted to digital signals by the ADC 8 and read by the digital subsystem 6.

In turn, the digital subsystem 6 outputs control signals which are converted to analogue signals by the digital to analogue convertor 7 and become inputs to the analogue subsystem 5. FIG. 2 shows two control signals, but the exact amount may vary depending on the design of the analogue subsystem. For example, it is possible to use only one control signal.

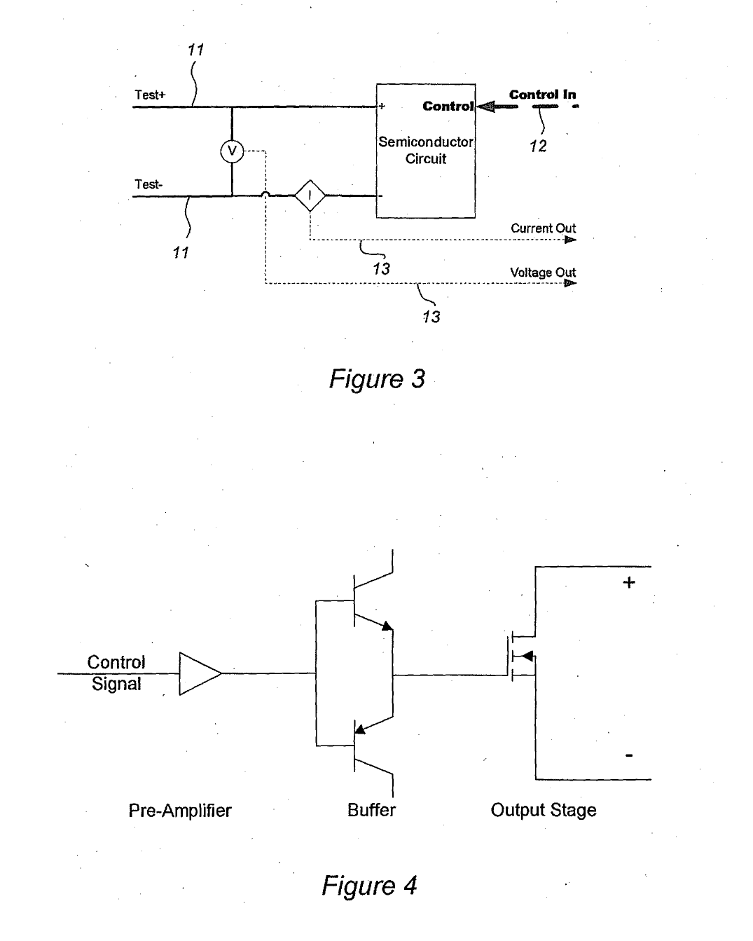

The analogue subsystem's purpose is to replicate the dynamic characteristics of an STA and measure the response of the device under test. The basic structure of the analogue subsystem is shown in FIG. 3 where the heavy lines 11 indicate the flow of power from the device under test and the dashed lines 12 and 13 indicate signal inputs and outputs respectively.

The current and voltage measurement circuit elements are designed so as not to load the device under test in any significant way. The use of a high valued shunt resistance and low valued series resistance for voltage and current measurements is preferred. Other methods such as magnetic sensing (Hall Effect or transformer) for current measurement are also possible.

The semiconductor circuit shown in FIG. 4, under the control of the digital subsystem is the embodiment of the time varying electrical load in the concept description shown in FIG. 2. One form of this circuit is shown in FIG. 4 which is a conceptual schematic with not all component details shown. This particular implementation uses only a single control input although the system described above provides for multiple inputs.

This circuit is a commonly used multistage amplifier. An integrated circuit amplifier is used as the first stage, providing gain, and the second stage is a push-pull bipolar buffer, providing low output impedance to drive the final stage formed by a MOSFET.

Over the duration of the simulated spark, the digital subsystem stores the measured voltage and current values, as well as generating the control signal. The primary logical components of the digital subsystem are the control logic and the output logic.

The control logic generates a vector valued signal in real time used as input to the semiconductor circuit. This signal can depend on time, past and present values of measured voltage, and past and present values of measured current

In an alternative method to the real time control system, it is possible to do en offline analysis of the power supply unit (PSU) and use this to mathematically calculate the required control signal for the electronics.

The purpose of the output logic is to provide a scalar valued score indicating the safety of the device under test. This safety score is calculated “offline” using the stored values of voltage and current measurements.

In an enhanced version of the procedure for electronic spark testing, an automated mufti-step process is applied, involving the following steps;
A. Energy source is connected directly to the electronic spark tester (EST);
B. EST performs a “static test” to determine Output Current to Output Voltage relationship of the energy source. This is done by applying a slow ramp shaped stimulus (ie: control signal) to the analogue subsystem, and measuring the current/voltage response of the energy source;
C. EST performs a “dynamic test” to determine how the energy source responds to fast changes in load conditions. This is done by applying a faster “step” stimulus to the analogue subsystem and measuring the time varying current/voltage as before;
D. Using the static and dynamic test results, and user entered values for the test load (a network of passive components connected between the spark tester and energy source), the EST calculates the stimulus required to yield the most energetic simulated spark;
E. Energy source is connected to the EST through the test load;
F. The spark stimulus calculated in step D is for applied to the analogue subsystem, and the resulting current/voltage response of the PSU is measured and recorded; and
G. The measured current/voltage is used to calculate the time varying power, which in Wm is used to calculate a quantitative measure of safety.

In this manner an electronic spark tester (EST) is provided to replace the previously used spark testing apparatus (STA). The key advantage of electrically simulating a spark, rather than an actually creating one via a STA, is control. Rather than generating a large number of sparks over a test period, relying on a random process to deliver an explosion, a worst case explosive spark can be characterised (in a similar manner to that shown in FIG. 1), and simulated on demand.

1. A method of assessing the safety of an energy source including the steps of applying a simulated spark load to the energy source and measuring the time varying current response to that load.

2. A method as claimed in claim 1 wherein the time varying current response measurement is used to determine the energy delivered to the load over the duration at the simulated spark.

3. A method as claimed in claim 2 wherein the time varying current response measurement is also used to determine the instantaneous power.

4. A method as claimed in claim 3 wherein the measured energy and instantaneous power are used to assess whether an explosion would have occurred.

5. A method as claimed in claim 1 wherein the energy source is connected to an electronic spark tester, including the following steps:
performing a static test b the electronic spark tester to determine the output current to output voltage relationship of the energy source:
performing dynamic test by the electronic spark tester to determine now the energy source responds to fast changes in load conditions; and
using the static and dynamic test results together with predetermined values for the spark iced to calculate the stimulus required to yield the most energetic simulated spark.

6. A method as claimed in claim 5 wherein the stimulus required to yield the most energetic simulated spark is applied to an analogue subsystem within the electronic spark tester and the resulting current/voltage response of the energy source is measured and recorded.

7. A method as claimed in claim 6 wherein the measured current/voltage is used to calculate the time varying power, which in turn is used to calculate a quantitative measure of ignition safely.

8. (canceled)

9. An apparatus for assessing the safety of an energy source including means for electronically generating a simulated spark load adapted to be applied to the energy source, and electronic means for measuring the time varying current response to that load.

10. An apparatus as claimed in claim 9 wherein the apparatus includes a digital subsystem adapted to output control signals and an analogue system configured to replicate the dynamic characteristics of a mechanical spark testing apparatus and measure the response of the energy source.

11. (canceled)
